(19) United States
(12) Patent Application Publication
(10) Pub. No.: US 2014/0008017 A1
(43) Pub. Date: Jan. 9, 2014

(54) EJECTION APPARATUS FOR LIFTING CHIPS OFF OF CARRIER MATERIALS

(71) Applicant: Fraunhofer-Gesellschaft zur Forderung der angewandten Forschung e.V, Munich (DE)

(72) Inventor: Markus Rießle, Waldkirch (DE)

(21) Appl. No.: 13/930,750

(22) Filed: Jun. 28, 2013

(30) Foreign Application Priority Data
Jul. 4, 2012 (DE) DE102012013 370.7

(51) Int. Cl. H01L 21/67

(52) U.S. Cl. CPC H01L 21/67011
USPC 156/293; 156/762; 29/700; 156/719

(57) ABSTRACT

An ejection device and a method for lifting a chip (2) from a carrier material (1) having at least one needle (4), wherein the needle (4) includes at least one cutting edge (7) for cutting through the carrier material (1). A mounting device for inserting and fixing at least one needle (4) in an ejection device for lifting a chip from a carrier material, having a plate for aligning the plane of the needle tips and a removable attachment that has a recess, wherein the removable attachment can be mounted on the ejection device in such a way that the recess serves to introduce the fixing material onto the needle ends. A method for fixing the needles in an ejection device is used, wherein the at least one needle to be fixed in the ejection device is melted in.

### BACKGROUND

The present invention relates to the field of handling electronic components that are normally processed on a wafer. After completion of the individual components on the wafer, the components are then diced. For this purpose, the wafer is mounted on a carrier material. The components or chips being diced are sawed on the carrier material whereas the carrier material itself is not sawed through. After sawing, the individual components are separated from one another on the carrier material by dice channels. The components must be lifted from the carrier material in order to be further processed. Specialized tools are used in the semiconductor industry for lifting the individual components or chips from the carrier material. Such ejection tools lift the chips using needles from the back side of the carrier material. A prior art tool of this type is shown in FIG. 1. In this case, the chip placed on the carrier material is lifted with needles rounded at their tips from the side that is attached to the carrier material. Generally, the carrier material is an adhesive carrier film. Lifting both the carrier material and the chip together loosens the adhesion of the carrier material at the edge of the chip. Residual adhesion remains between the carrier material and the chip. The chip is then removed by means of a vacuum gripper to be further processed. In this step the carrier material is usually not severed from the ejection tool.

EP patent EP 0 565 781 B1 also shows an ejection tool for the semiconductor industry. With the aid of an ejector needle disposed in a fixed position the chip is lifted through the adhesive carrier film. In this process, the carrier film is not necessarily pierced by the conical needle. If it is pierced, only a small hole results, so that when further raising the needle the carrier film, due to the conical, tapered shape of the needle, is also further lifted.

The problem that arises during the process of lifting the diced chips from the wafer composite is the risk that the chip will break or that the adjacent chips will be damaged. The drawback of the prior art in this regard is that either residual adhesion forces of the adhesive carrier film act on the chip while it is being removed by the take-up tool, generally a vacuum gripper, from the ejection tool, or that when the chip is first lifted by the needle of the ejection tool, too much pressure and tension is applied to the carrier material as the carrier material is also being lifted by the needle, and therefore to the chip being lifted and to the adjacent chips, whereby the chips break.

Therefore, the object of the invention is to reduce the risk of chip breakage and thereby increase the yield of functioning chips. In particular for chips that are especially thin, that are made of a particularly brittle material or that lack a rectangular shape because they include, for example, monolithically integrated wave guide antennas, a method and a device are provided which enable damage-free lifting of the chip and which increase the yield of undamaged chips.

### SUMMARY

An ejection device is provided for lifting a chip from a carrier material having at least one needle, wherein the needle includes at least one cutting edge. The advantage of the cutting edge is that when lifting the chip from the side adjacent the carrier material, the carrier material is cut through during lifting by the at least one needle. This prevents the carrier material from also being lifted during the lifting process and pressure from being exerted on the adjacent chips. To lift the chip the needle is pressed against the carrier material and the overlying chip. Here, the carrier material is lifted slightly only initially until the tip of the needle lightly pierces the carrier material, as the needle is further raised the carrier material is cut through due to the cutting edge along the front portion of the needle, and is as a result no longer lifted.

The penetration resistance of the needle is reduced as a result of the cutting edge, and the carrier material is cut through as a result of the pressure of the cutting edge of the needle against the carrier material during the lifting process. Thus, the mechanical forces acting on the chips during the lifting process are significantly reduced. In addition, there are no residual adhesion forces of the carrier material acting on the chip when the latter after being lifting is removed from the ejection tool by a vacuum gripper to be further processed.

Here, a needle is seen to be a rod-shaped device wherein it is the front portion of the needle that is involved in the lifting process. The foremost end of the needle is designated the needle tip. During the lifting process, it is the needle tip that first comes into contact with the carrier material and with the chip and supports the chip during lifting.

The end opposite the needle tip is designated the needle end.

It was seen as advantageous that the grinding of the front portion of the needle has at least one cutting edge that cuts through the carrier material during the lifting process. The needle is sharpened so as to form a sharp edge which cuts through, that is severs, the carrier material. The cutting edge is preferably formed as a lateral edge along the front portion of the needle. In this configuration the front portion of the needle can be shaped as a knife with a sharp lateral edge or also two opposing sharp lateral edges. The cutting edge is ground to form a wedge-shaped lateral edge. Preferably the cutting edges are prepared so that the needles also gradually taper in the direction of the needle tip.

Thus, according to the invention, to lift a chip from a carrier material a needle is used which includes at least one cutting edge for cutting through the carrier material.

A carrier material in the form of an adhesive carrier film is preferably used, on which the wafer is placed for the chips to be diced and which adheres to the former. This can be a plastic film, for example.

The chip to be lifted is, for example, a semiconductor chip fabricated on a semiconductor wafer. The embodiment of the ejection device according to the invention and the method according to the invention are advantageous in particular for chips for MMICs that are produced from III/V semiconductor material, for example, chips produced from GaAs or InP thinned to 20 on down to 100 μm.

Another embodiment of the extraction device for lifting a chip from a carrier material includes at least one needle, wherein the diameter of the needle is smaller than or equal to 0.25 mm. This choice of needle diameter ensures that the penetration resistance of the needle in the carrier material during the lifting process is minimal. Based on this diameter it is also possible for the needle to be ground on the front section of the needle. In particular, it is possible for the needle to have at least one cutting edge.

In a further embodiment the needle of the ejection device includes three cutting edges for cutting through the carrier material. By using three cutting edges the needle cuts through, that is, severs the carrier material as the chip is lifted. Preferably, the cutting edges are prepared such that the needle also gradually tapers in the direction of the needle tip.

Thus, to lift a chip from a carrier material, a needle is used that has three cutting edges for cutting through the carrier material.

The cutting edges are formed along the front portion of the needle in such a way that three sharp lateral edges, for example pyramid-shaped, extend along the front portion of the needle. The former cut through the carrier material along the lifting path as the needle is raised. In this way the chip is lifted from the carrier material and detached from the chip composite.

In a further embodiment the ejection device comprises a needle holder with holes for receiving at least one needle, in addition the ejection device includes a needle head and a compression spring, wherein the needle head and the needle holder can be assembled so that when assembled, the needle head and the needle holder via the compression spring are moveable relative to one another. The advantage of this is that during operation, the ejection device functions so that the needle tips are recessed in the ejection device so that the tips remain protected. During operation the carrier material with the wafer travels over the needle head and cannot damage the recessed tips. Not until the chip being ejected is positioned over the needle head are the needles forced in the direction of the needle head and the needle tips come into contact with the overlying carrier material and the chip mounted thereon.

Designated as compression springs are components which yield under stress and upon release return to their original shape, are therefore elastically resetting.

As a further embodiment of the ejection device, the ejection device can be fitted with needles based on the area of the chip to be lifted, wherein the density of the needles is at least three needles per 1 mm² of chip area. Thus, the needle density of the ejection device in this embodiment is selected so that at least one needle is positioned on 0.33 mm² of chip area. The advantage of this is that the problem of concentrated forces acting on the chip during lifting is distributed to multiple needles. Such pressure distribution reduces the flexural moment on the chip, since multiple points on the chip are affected simultaneously. As a result the chip breaks less easily during the lifting process. Since according to the invention the selected diameter of the needles used in a preferred embodiment is particularly small, the needle density per chip area can be increased, as opposed to the prior art which operates with needle diameters of 0.5 to 0.7 mm. Additional needle densities used according to the invention are preferably 4 needles per 1 mm² of chip area, that is, at least one needle is positioned on 0.25 mm², and at least 5 needles per 1 mm² of chip area, that is, at least 1 needle is positioned on 0.2 mm² of chip area. Thus, the needle density selected according to the invention falls preferably between 3 to 5 needles per 1 mm² of chip area.

In a further embodiment the at least one needle is fixed in the needle holder such that the at least one needle is fixed in the needle holder by means of a hotmelt adhesive. Thus, the needle is fixed in a rigid medium in the needle holder. This means that the at least one needle is introduced into a liquid medium in the needle holder during production of the ejection device, or the liquid medium is applied to the needle in the needle holder and in the subsequent process as the medium solidifies or cures, the needles become fixed in the needle holder. The advantage of such fixing is that when fixing the needle in the ejection device no mechanical forces act on the needle which lead to a deformation of the needle, as is the case in the prior art. In the prior art the needle is fixed with an allen screw, which can cause the needles to bend or shift.

A particularly suitable medium for fixing the needles is a hotmelt adhesive which by changing temperature changes from a solid to a liquid state or conversely, from a liquid to a solid state. It is a solid at room temperature. It is applied in melted form and subsequently adheres to the respective surface when cooled again to a temperature below melting point.

The method for fixing the needles in an ejection device for lifting a chip from a carrier material includes the following steps:
inserting the at least one needle in a needle holder of the ejection device
fixing the needles, whereby the ends of the needles are fixed in the needle holder by means of an adhesive as a result of the adhesive solidifying or curing.

The advantage of the method is that the needles in the ejection device are mounted in such a way that they are not tensed or warped. This is particularly important when multiple needles must be inserted in order, for example, to cover a larger chip area, and for that purpose the needle tips must be aligned as precisely as possible in a single plane.

Adhesives are non-metallic materials that bind substrates by means of adhesion or cohesion. Hotmelt adhesives have proven to be especially suitable for fixing needles, particularly because the former are easily removable. A hotmelt adhesive that can be removed with a dissolvent is especially suitable. A hotmelt adhesive is applied in liquid form, then adheres to the respective surface when cooled again to a temperature below melting point. Particularly suitable are hotmelt adhesives containing wax or hotmelt adhesive consisting of wax.

The method for fixing at least one needle in a needle holder (8) of an ejection device for lifting a chip from a carrier material further includes the following steps that precede the fixing of the needles,
introducing the at least one needle into the at least one hole of the needle holder, wherein one needle each is introduced into one hole each of the needle holder
aligning the plane of the needle tips, wherein the needles guided loosely in the holes of the ejection device are aligned with their needle tips on a level plate as a result of their own weight.

This method step ensures that the needles are seated in the correct position prior to fixing and the plane of the needle tips is set.

In a further embodiment of the method the adhesive is a hotmelt adhesive, the latter being applied to the needle ends in the form of a granulate, and in a further step the granulate is melted and solidified in a further step.

The method claimed herein ensures that the needles are fixed to the tool in such a way that when fixed they do not become misaligned.

In a further embodiment of the method for fixing at least one needle in a needle holder of an ejection device for lifting a chip from a carrier material, a still further method step is implemented. In this step, once the adhesive is applied and before the adhesive solidifies, the needle holder is moved downward a short distance, for example, approximately 0.5 mm in the direction of the flat plate on which the needle tips are aligned in order prior to solidification of the adhesive to ensure once again an alignment of the needle tips in a plane. Such movement of the needle holder in the direction of the flat plate corrects for any slight upward movement of the one or other needle caused by dispersal of the adhesive and forces all the needle tips again in the direction of the flat plate.

A mounting device is used for mounting the ejection device. The mounting device according to the invention for inserting and fixing at least one needle in an ejection device includes a plate for aligning the plane of the needle tips and a removable attachment and a connecting piece, wherein the plate (12) can be connected to the removable attachment (13) via the connecting piece (14) in such a way that the removable attachment (13) can be attached to the needle holder, needle head and compression spring via the connecting piece (14), such that after the fixing process the needles (4) are recess mounted in the ejection device. The advantage of this feature is that once the needles are mounted they are situated somewhat recessed in the ejection tool and the needle tips are protected as a result. Only when the ejection tool is used to lift the chip are the needles forced out of the ejection tool.

According to a further embodiment of the mounting device, the removable attachment has a recess and the removable attachment together with the recess can be mounted over the needle holder of the ejection device in such a way that the recess functions to introduce the fixing material onto the needle ends in the needle holder

A method according to the invention for lifting a chip from a chip composite mounted on a carrier material comprises the following steps:—lifting the chip with the aid of at least one needle, wherein the chip is lifted from the side of the chip facing toward the carrier material, wherein lifting occurs in that the at least one needle includes at least one cutting edge and the at least one needle through the carrier material lifts the chip and during lifting the carrier material is cut through by the cutting edge.

According to a further embodiment of the method for lifting a chip from a carrier material, the at least one needle has a diameter that is smaller or equal to 0.25 mm. The advantage of this is that needle severs the carrier material during lifting. In particular, including a cutting edge on the front end of the needles ensures that the carrier film on which the chips rest is lifted barely or not at all during the lifting process. As a further advantage, because there are virtually no expansion stresses acting on the foil, the adjacent chips that are momentarily not directly involved in the lifting process are not damaged, which normally occurs as a result of the shifting of the chip when the carrier film is lifted during the removal process. By lifting the carrier film the edges of the adjacent chips would slide onto one another and become damaged as a result. This is prevented by the present invention. Moreover, there are no residual adhesion forces of the carrier film acting on the chip when the latter is lifted with a vacuum gripper from the side opposite the needle to be further processed.

According to a further embodiment of the method for lifting a chip from a carrier material the following steps are implemented:—lifting the chip using an ejection device having at least one needle, wherein the chip is lifted from the side of the chip that faces toward the carrier material, wherein the at least one needle through the carrier material lifts the chip, characterized in that the ejection device is fitted with needles based on the area of the chip to be removed, specifically, with a needle density of at least one needle per 0.33 mm² of chip area.

This ensures that a sufficient number of needle tips are positioned per chip area in order to distribute the mechanical forces uniformly across the chip area, and so that too great a pressure does not build up locally at one point on the chip. In this regard, it has been found that per 1 mm² of chip area a distribution of at least three, at least four or at least five needles across this chip area ensures an optimum pressure distribution.

An ejection device according to the invention is especially suited for fabrication machines used to lift a chip from a carrier material and to take up the chip for further processing, wherein the chip is lifted from the carrier material by an ejection device according to the invention, and with a take-up tool the chip is removed from the ejection device. The ejection device ensures that the chip is detached from the chip composite and is presented so that a take-up tool is able to take the chip without damage to itself or to the adjacent chips. Fabrication machines of this type in the semiconductor industry then deposit the chip, for example, in a packaging. Semiconductor fabrication machines of this type that have an ejection device and a take-up device are, for example, die bonders. The take-up tool is generally a vacuum gripper that removes the chip from the needle from the side opposite the needle of the ejection device. It is advantageous in the case of this highly automated process if the chip is completely separated from the adhesive carrier film and no residual adhesive forces are affecting the chip which could strain the chip as it is being taken up. This is ensured with the ejection device according to the invention by cutting through the carrier film during the lifting process.

### BRIEF DESCRIPTION OF THE DRAWINGS

Further advantages and features of the present invention are described below with reference to FIGS. 1 through 7.

FIG. 1: shows an ejection device according to the prior art

FIG. 2: shows an ejection device according to the invention during lifting of a chip from a chip composite

FIG. 3: shows a needle according to the invention with a corresponding grinding at the front end of the needle

FIGS. 4a and 4b: show a specific embodiment of the ejection device with needles, needle holder, compression spring and needle head from two different perspectives

FIG. 5: shows schematically an embodiment of the mounting device

FIG. 6: shows an ejection device in which the needles are extended

FIG. 7: shows a needle with a triangular cut on the front portion of the needle

### DESCRIPTION OF PREFERRED EMBODIMENTS

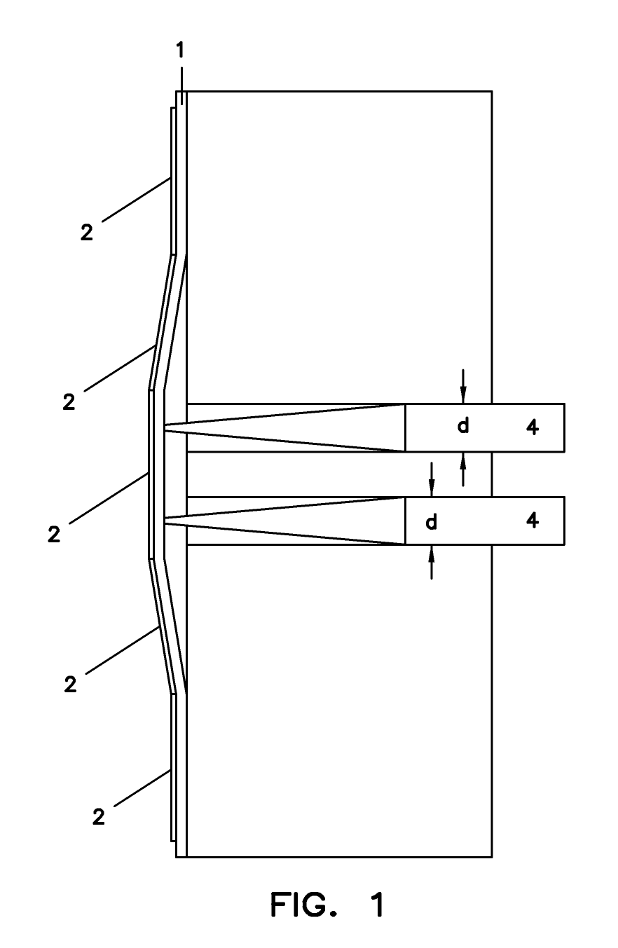

FIG. 1 shows how in the prior art a chip is lifted from a carrier material. A carrier material 1, for example, an adhesive carrier film, e.g. a self-adhesive carrier film, 0.9 mm in thickness, for example, is provided with a number of chips 2. During operation the carrier material with the wafer or chip composite travels over the ejection device, whereby the chip to be ejected is brought into position over the ejection device. From the back side of the carrier film the ejection device lifts the chips with the needles. The prior art needles are 0.5 to 0.7 mm in diameter. By lifting the chips from the back side, that is the side facing toward the carrier film, the adhesive carrier film is detached at the edge of the chips, whereby in the prior art, needles are used with strongly rounded, conically-shaped tips so that during the lifting process the needles do not pierce or sever the carrier material. In this way, under the pressure of the needles, the carrier material is also lifted and is deformed into a generally parabolic shape. The carrier material is detached only from the edge of the chip where the carrier material is held down, since it is fastened in a frame and moreover is vacuum suctioned on. Where the film is nevertheless pierced, a small hole is formed. When the needles are raised, the carrier film is raised along with them as a result of the conical shape of the needles. At this point the chip is ready to be removed by a vacuum gripper, i.e. from the side of the chip opposite the carrier material. According to the prior art, a residual adhesion from the adhesive layer of the carrier material remaining on the chip acts on the chip such that during removal with the vacuum gripper the chip is at risk of breaking. A further drawback in this regard, as can be seen in FIG. 1, is that when the carrier film is lifted, the adjacent chips are also lifted and tipped in the process, resulting in the risk of their edges in turn sliding against the adjacent chips and becoming damaged.

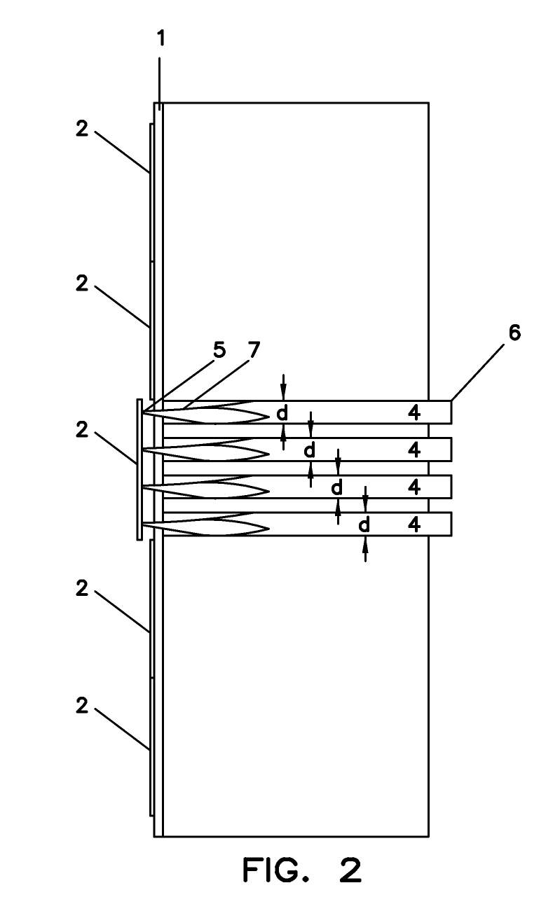

This method according to the prior art is especially problematic when it comes to semiconductor wafers that are severely thinned during the fabrication process and have a wafer thickness of, for example, just 20 to 100 μm. Such thin wafers are in particular the product of MMIC processing (monolithic microwave or millimeter wave integrated circuits). These thinned wafers are mounted on a carrier material in order for the chips to be diced. The carrier material may be an adhesive carrier film. The film is stretched across a frame and the chips to be diced are sawed on the carrier film without the carrier film itself being sawed through. Sawing is done mechanically or with a laser beam. The sawed chips are separated from one another by a narrow dicing channel 5 μm to 30 μm in width and lie separately from one another on the carrier film. The prior art method is associated with high damage rates, especially for MMICS made of chips fabricated from III/V semiconductor material, for example, from GaAs or InP and thinned from 20 on down to 100 μm. In this case, the method according to the invention shown schematically in FIG. 2 is advantageous in increasing the yield of functioning chips.

In FIG. 2 the chips 2 to be lifted rest on a carrier material 1, for example, an adhesive carrier film, and in this example the chip 2 is raised by needles 8 (4 needles are concealed) which lift the chip 2 from the carrier film and the chip composite. According to the method of the invention the ejection device is produced so that as the chip is lifted by means of the ejection device, at least one needle cuts through the carrier material during lifting. In the example in FIG. 2 there are at least 8 needles, each of which are prepared with a cutting edge 7. The needle tip slightly pierces the carrier film and the cutting edge, under pressure generated by the needles on the carrier film during lifting or raising, cuts through the carrier material along the lifting path.

A needle is seen as a rod-shaped device. The front portion of the needle is the portion involved in the lifting process. The needle tip is the foremost end of the needle by means of which the pressure is transferred to the chip and on which the chip rests when it is lifted. This is followed by the front portion of the needle.

The needles according to the invention may be produced from a needle blank, for example, a wire pin, the cross-section of which may be of any desired shape, for example, shapes that are round, angular or flat in cross-section. In order for the needle to pierce the carrier film as effortlessly as possible, it was found according to the invention, to prepare the front portion of the needle so that the part of the needle projecting above the original plane of the carrier film during lifting is prepared with at least one cutting edge. For this purpose, the front portion of the needle is provided with at least one edge that functions as a cutting edge for the carrier material and is sharpened and includes a surface polished as smoothly as possible. This results in minimal penetration resistance of the needle in relation to the carrier material due to the wedge-shaped cutting edge, and during the lifting process the carrier material is cut through by the at least one cutting edge of the needle. Preferably, the needle can be prepared so that it tapers or becomes thinner toward the needle tip.

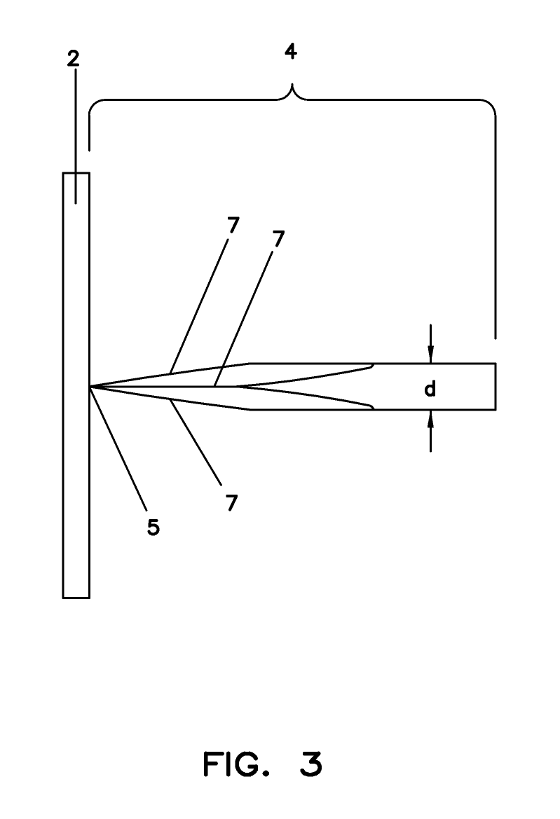

An especially preferred embodiment of a needle according to the invention is shown in FIG. 3. This needle 4 has a triangular cut thereby giving rise to three cutting edges 7 which cut through the carrier material 1 during the lifting process.

In particular the front portion of the needle can be thinned toward the needle tip, whereby at least three lateral edges are prepared along a section of the front portion of the needle. The cut with the three cutting edges results in a triangular-shaped cross-section at the front portion of the needle.

Thus, a needle is used for lifting a chip from a carrier material that has three cutting edges.

According to the invention, it was found that the penetration resistance of the needle in the carrier material is also significantly reduced if the needle is fabricated from a wire pin with a diameter that is smaller or equal to 0.25 mm. Conventional needles used in the prior art have a diameter of from 0.5 to 0.7 mm. Such a needle thickness offers the carrier film too great a surface area such that needles of this type generally fail to pierce the carrier material. Even if a tip based on this needle diameter has a cut that sharply tapers toward the tip of the needle, such a needle offers too much resistance, with the result that when the needle is raised further the carrier film is pulled and raised along with it. In that vein, according to the invention the ejection device is operated with a needle with an appropriately small diameter such that the needle is able to penetrate the carrier material. Together with a grinding on the front portion of the needle toward the needle tip, which includes in particular at least one cutting edge it was found that as a result the carrier film is barely raised as the chip is lifted off. With a needle diameter of 0.25 mm the needle tip can be finely worked accordingly.

An ejection device with multiple needles is called for depending on the shape of the chip to be lifted or depending on the size of the chip area. Thus, the ejection device can be fitted with needles depending on the area of the chip to be lifted. Once raised, the chip rests as if on a cushion of needles, as is also shown in FIG. 2. As a result the chip no longer breaks. According to the invention four needles are inserted in the ejection device, given a chip area of 1 mm². By selecting a smaller diameter for the needles used, it is possible to increase the needle density. For example, a chip with an area of 1×1.5 mm² was lifted simultaneously with five needles. Using multiple needles to lift a chip reduces the flexural moment acting on the chip as a result of the pressure during lifting. This reduces the risk of the chip breaking. Even very large chips can be lifted using the ejection device according to the invention. As a further example, a chip 4×1 mm² in size was lifted with 12 needles. This indicates that according to the invention needle densities are used wherein one needle is positioned on a chip area of 0.33 mm².

According to the invention it is preferable to operate with a needle density amounting to at least 1 needle per 0.25 mm².

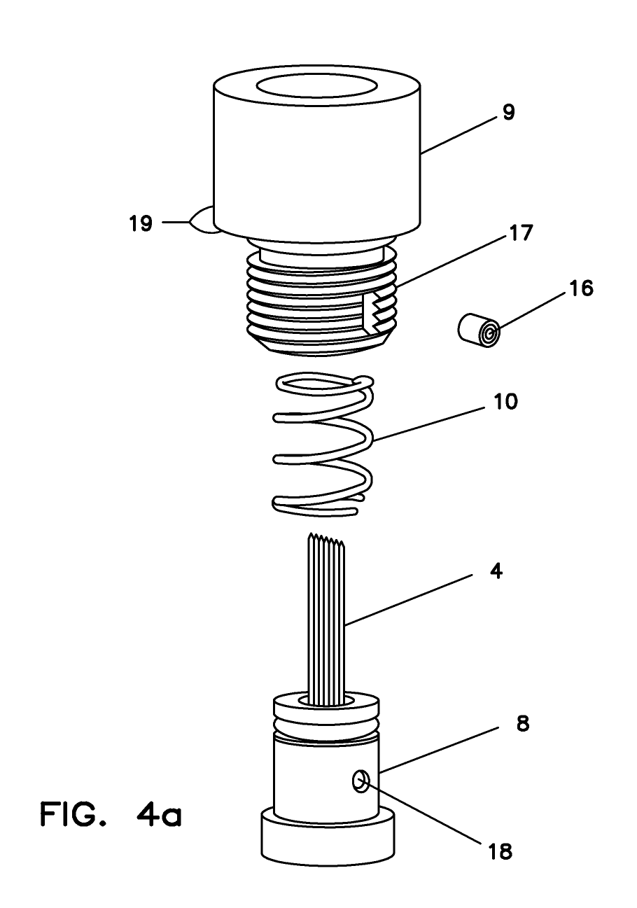

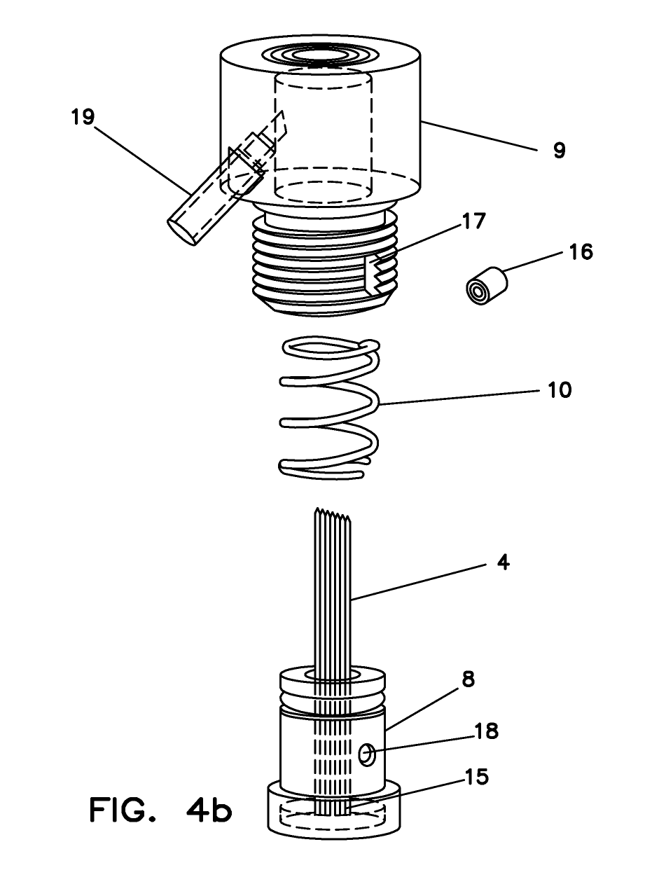

FIGS. 4a and 4b show a specific embodiment of the ejection device. The ejection device is composed of a needle holder 8 in which the needles 4 can be fixed. In this example, the needle holder 8 of the ejection device is prepared with 12 needles. The needles 4 are accommodated in holes 15 of the needle holder. FIGS. 4a and 4b show the ejection device disassembled. In the assembled ejection device the needle holder 8 is inserted via a compression spring 10 into the needle head 9 and thereby attached. The allen screw 16 serves to connect the screw hole 18 in the needle holder to the slotted hole 17 of the needle head 9. The compression spring 10 enables the needle head 9 and the needle holder 8 to be pressed together. That means, needle head 9 and needle holder 8 can be moved relative to one another when joined together. The advantage of this is that the needle tips 5 when non-operational are situated inside the needle head 9. The needle tips are recess mounted approximately 0.5 mm below the surface of the ejection tool, in this case of the needle head 9. During operation the carrier film 1 with the wafer travels over the needle head 9 and is thus cannot damage the needle tips 7. When the corresponding chip 2 is correctly positioned, the needle tips 7 are forced upward out of the needle head 9 and impact the chip 2 located above.

Also visible in FIGS. 4a and 4b is a vacuum suction connection 19 over which a hose is slipped for applying a vacuum at the vacuum holes 20 during operation of the ejection device. During operation of the ejection device, the vacuum holds the carrier material in place over the vacuum holes by means of a vacuum and thereby facilitates the lifting of the chip from the carrier material. The carrier material is suctioned and held in place by the vacuum.

The subject matter of the invention in one embodiment is to fix the needles in the needle holder in such a way that they are not warped during the fixing process. It is important, especially when the ejection device is fitted with more than one needle, that the needles tips are aligned in one plane. In this way, the mechanical forces acting on the chip as a result of the pressure of the needles is optimally distributed. For this reason, the ejection device is operated preferably with needles that are fixed in a rigid medium. By contrast, in the prior art mechanical force is expended on one side when fixing the needles in the ejection tool. The needles of the prior art are secured in their mounting holes by alien screws. By tightening the alien screws it is possible for the needles to shift slightly or become stressed in the holes, thereby no longer ensuring a uniform alignment of the needle tips.

The present invention has found that it is advantageous to fix the needles using a medium that, when solidified, permanently fixes the needles in the ejection device. Particularly suited for this is a hotmelt adhesive that changes from the liquid to the solid state when the temperature changes. The needles are guided into the holes of the needle holder, whereby the medium is applied to the needle ends in the needle holder, is applied either in the liquid state or is liquefied subsequent to application. Subsequent solidifying bonds the needles via the medium to the needle holder. In this way, the needles are fixedly mounted in the needle holder. After the ejection device is used, the needles can be removed again by means of a suitable solvent. For this reason a hotmelt adhesive is particularly suited since it can be removed completely by being bathed in solvent. For this purpose, the needle holder together with the needles is immersed in a solvent bath. A suitable solvent is acetone, for example. The hotmelt adhesive is dissolved in this way and the needles can be removed from the holes, and the ejection device can be prepared once again. A correspondingly suitable hotmelt adhesive is Crystalbond 509™.

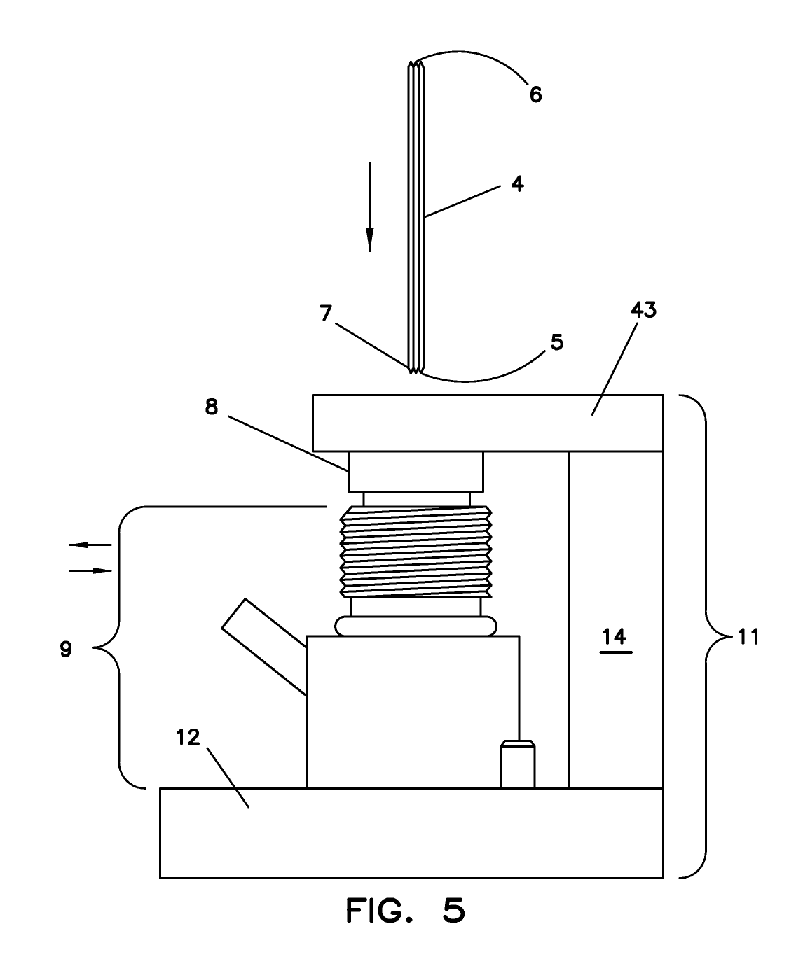

FIG. 5 shows a schematic view of a mounting device 11 used to insert and fix the needles 4 in place in the ejection device. The mounting device 11 consists of a flat plate 12 on which the needle tips 5 rest during mounting, and of a removable attachment 13 which is attached for mounting on the ejection device in such a way that a recess disposed in the removable attachment 13 is mounted over the needle holder 8. The removable attachment 13 is connected to the flat plate 12 by the connecting piece 14. In this configuration the needle holder is forced down approximately 0.5 mm by the removable attachment onto the compression spring.

In this case, the needle holder 8 can either be forced by the removable attachment 13 onto the compression spring 10 when the ejection device is first introduced into the mounting device,
that is, before the needles 4 are inserted into the holes of the needle holder 8 and thus retained for further assembly, or the mounting device is employed so that the ejection device is first mounted in the mounting device in such a way that the needle holder is not yet forced down onto the compression spring. Only once the needles 4 have been inserted into the holes 15 and only once the adhesive is applied to the needle ends in the needle holder 8 is the removable attachment 13 moved downwardly by means of a screw or eccentric, in so doing, forces the needle holder 8 onto the compression spring 10 of the ejection device, and by means of the adhesive draws downward again any needles 4 that were pulled upward. This better ensures that all of the needle tips 5 are resting on the flat plate 12 when the adhesive solidifies.

To install the needles, the needles 4 are inserted into the holes of the ejection device. In so doing, it is preferable to insert one needle each into one hole each of the ejection device. The needles rest loosely in the holes of the ejection device and, as a result of their own weight, rest with their needle tips on the flat plate 12. The flat plate 12 serves to align the plane of the needle tips. Therefore, the plate 12 includes a polished, very flat surface. The error differential of the plane of the needle tips is reduced by the mounting device according to the invention to a few μm. At this point the needles are fixed in the ejection device. In this process a hotmelt adhesive is preferably applied to the needle ends in the needle holder, the hotmelt adhesive then melted and subsequently solidifies. To liquefy the hotmelt adhesive, the mounting device 11 together with the ejection device is placed on a hot plate and heated by the hot plate to approximately 120° C. For this purpose, the mounting device is composed of a good thermally conductive material, thus for example, a metal plate, metal connecting piece and metal removable attachment. Tool steel is especially suitable in this regard and is also very easily ground to form a flat plate 12, in particular, tempered tool steel. The hotmelt adhesive is applied via the recess which forms an opening in the removable attachment 13 to the needle holder 8 and the needle ends 6 disposed therein, is heated and binds the needle ends 6 to the needle holder 8 and securely fixes said needles after solidifying. This ensures that the needles are securely fixed to the tool and yet are not misaligned as a result of the fixing process. Here, a hotmelt adhesive is especially suitable that is advantageously applied as a granulate and subsequently melted. Moreover, the mounting device is preferably designed so that the removable attachment is mounted and screwed tight, thereby pressing the needle holder down approximately 0.5 mm onto the spring. The needles are then fixed. Once the ejection device is removed from the mounting device following the fixing process, the needles are recessed by approximately 0.5 mm in the ejection device.

As an option, the needles can be inserted into the ejection device under a microscope. For this purpose the ejection device is in the assembled state, consisting of needle holder, compression spring and needle head. The needle head rests on a preassembly aid made of plastic so that the tips of the needles come to rest against a soft plastic as the needles are inserted into the holes. This ensures that the tips of the needles are not damaged upon impact. With the help of this plastic pre-assembly aid the ejection device can be placed upside down on the mounting device. The pre-assembly aid is then removed. At this point the removable attachment is mounted on the ejection device and screwed tight, as described.

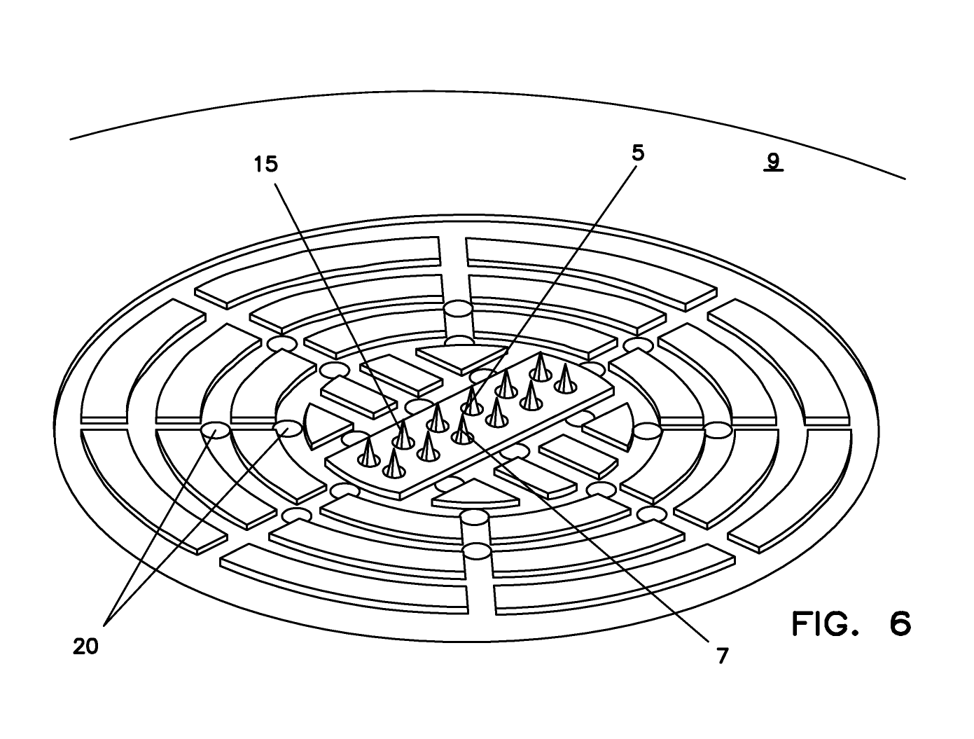

FIG. 6 shows an ejection device prepared with needles 4, wherein in this example the needle head 9 is visible from above and the needles 4 are pushed out. The holes 15 for the needles in the needle head 9 are visible in the drawing. When using needles with a diameter of 0.25 mm, the holes 15 are approximately 0.27 mm in diameter.

As the chip is lifted off the carrier material a vacuum flows through the vacuum holes 20 to the carrier material, thus pinning the carrier material to the needle head.

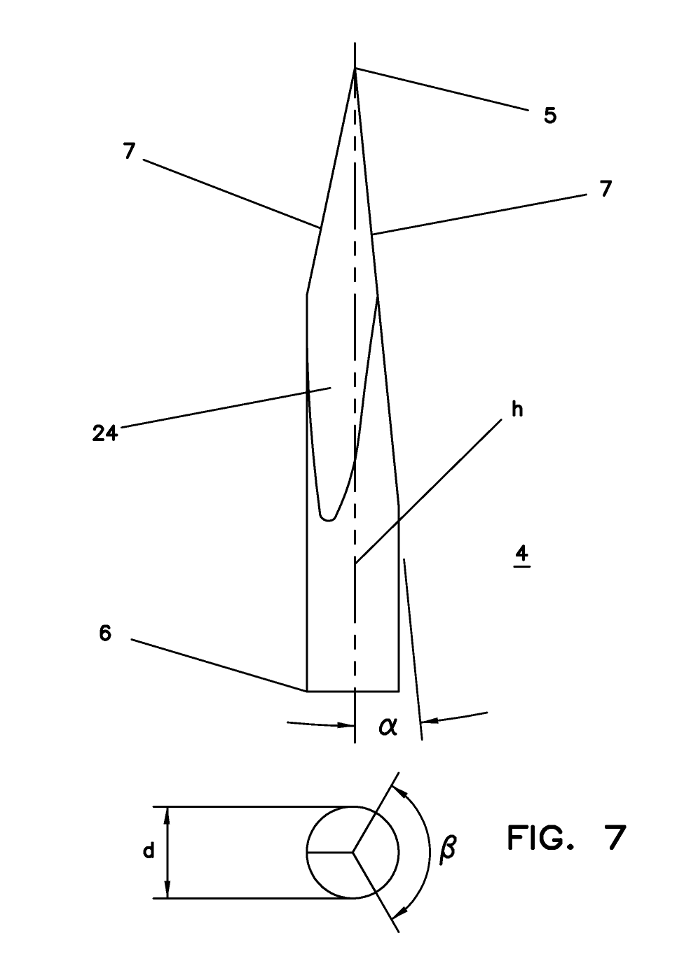

FIG. 7 shows the preparation of a needle according to the invention which has three cutting edges (one is concealed), formed as sharp, wedge-shaped lateral edges, at the front portion of the needle and which taper toward the tip of the needle so that the tips are formed correspondingly sharp. Thus, as the needles are lifted, when the needles press against the carrier material and the chip resting thereon, the carrier material is initially pierced, and then as a result of further pressure from the needles and with that the high pressure forces of the cutting edges against the carrier material, said carrier material is cut through by the cutting edge as the needle is raised to the point at which the chip is presented for take up by the take-up tool. The pressure against the carrier material or against the carrier film as a result of the needles pressing against the carrier material and against the chip is thus removed from the carrier film as a result of it being cut through, such that the latter is not warped or raised further, and thus also with barely any pressure on the chip itself and no slipping of the adjacent chips, no damage is done to the chips. In addition, the carrier film is completely detached from the chip so that when the chip is taken up by the take-up tool, there are no residual adhesion forces holding the chip down.

In the drawing, the lateral edges 7 are drawn as straight lateral edges. However, they can also be ground to arch inwardly or outwardly. The lateral faces 21 between two cutting edges can be worked to form a flat surface between the two cutting edges. However, the lateral faces 21 can also be ground to form an arc between the lateral edges. To increase the sharpness of the lateral edges the lateral faces can in particular be ground to arch inwardly.

The length of the needles used here is 29 mm. However, this can be adapted depending on the ejection device and the fabrication machine, and is typically between 10 mm and 30 mm. The prior art operates with conically shaped tips. Now, according to the invention sharpened lateral edges are ground along the front portion of the needle.

The three cutting edges are ground from a wire blank at an angle β relative to one another. This angle can be approximately 120°, but can also differ from this so that the three cutting edges do not lie at the same angular distance from one another. The preferred diameter on the basis of which the needle is ground is smaller or equal to 0.25 mm. The respective angle α between height h and lateral edge or cutting edge 7 can be selected as required. The height h is the perpendicular that is dropped from the needle tip to the base plane, wherein the base plane is the cross-sectional area of the needle end 6. In this case, a preferably selected angle α is 4° to 8°.

### LIST OF REFERENCE NUMERALS

(1) carrier material
(2) chip
(4) needle
(5) needle tip
(6) needle end
(7) cutting edge
(8) needle holder
(9) needle head
(10) compression spring
(11) mounting device
(12) flat plate
(13) removable attachment
(14) connecting piece between (12) and (13)
(15) hole for needles
(16) screw
(17) slotted hole
(18) screw hole
(19) vacuum suction connection
(20) vacuum holes
(21) lateral surface
(d) diameter
(h) height
(α) angle α
(β) angle β

1. Ejection device for lifting a chip (2) from a carrier material (1)
having at least one needle (4),
wherein the needle (4) includes at least one cutting edge (7) for cutting through the carrier material (1).

2. The ejection device for lifting a chip (2) from a carrier material (1) according to claim 1, wherein the cutting edge (7) is formed as a lateral edge along the front portion of the needle (4).

3. The ejection device for lifting a chip (2) from a carrier material (1) according to claim 1 or 2, having at least one needle (4), wherein the diameter (d) of the needle (4) is smaller or equal to 0.25 mm.

4. The ejection device according to claim 1 or 2, wherein the needle (4) includes three cutting edges (7) for cutting through the carrier material (1).

5. The ejection device according to claim 4, characterized in that the cutting edges (7) are formed as three sharp lateral edges along the front portion of the needle (4).

6. The ejection device according to claim 1 or 2, wherein the ejection device comprises a needle holder (8) with holes for accommodating at least one needle (4), the ejection device further comprising a needle head (9) and a compression spring (10), wherein the needle head (9) and the needle holder (8) can be assembled in such a way that the needle head (9) and needle holder (8) in the assembled state are movable relative to one another by virtue of the compression spring (10).

7. The ejection device according to claim 1 or 2, wherein the ejection device can be fitted with needles (4) depending on the area of the chip (2) to be lifted, wherein the needle density is at least three needles per 1 mm² of chip area.

8. The ejection device according to claim 6, wherein the at least one needle (4) is fixed in the needle holder (8) by means of a hotmelt adhesive.

9. Method for fixing at least one needle in a needle holder (8) of an ejection device for lifting a chip from a carrier material, wherein the needle includes a needle tip and an opposing needle end,
comprising the steps of:
inserting the at least one needle into a needle holder of the ejection device,
fixing the needles, wherein the ends of the needles are fixed in the needle holder by means of an adhesive as a result of solidification or curing of the adhesive in the needle holder,
wherein the adhesive is a hotmelt adhesive and is applied to the needle ends in the form of a granulate, is melted in a further step and becomes solidified in yet a further step.

10. Method according to claim 9, wherein the fixing of the needles is preceded by the following steps:
inserting the at least one needle into at least one hole of the needle holder, wherein one needle each is inserted into one hole each of the needle holder
aligning the plane of the needle tips, wherein the needles loosely guided in the holes of the ejection device are aligned by virtue of their own weight with their needle tips on a flat plate.

11. The method according to claim 9 or 10, wherein after the hotmelt adhesive-granulate is applied and the hotmelt adhesive-granulate has melted, still prior to solidification of the hotmelt adhesive, the needle holder is moved a short distance downward in the direction of the flat plate in order to check an alignment of the needle tips on the flat plate prior to solidification of the hotmelt adhesive.

12. A mounting device (11) for inserting and fixing the at least one needle (4), wherein the needles comprise a needle tip and a needle end opposite thereof, in an ejection device for lifting a chip from a carrier material comprising
a plate (12) for aligning the plane of the needle tips
and a removable attachment (13),
and a connecting piece 14,
wherein the plate (12) can be connected to the removable attachment (13) via the connecting piece (14) in such a way that the removable attachment (13) can be attached via the connecting piece (14) to the needle holder (8), the needle head (9) and the compression spring (10) of the ejection device in such a way that after the fixing process the needles (4) are recess mounted in the ejection device.

13. The mounting device according to claim 12, wherein the removable attachment (13) includes a recess, and the removable attachment (13) is mountable over the needle holder of the ejection device such that the recess serves to introduce the fixing material onto the needle ends in the needle holder.

14. A method for lifting a chip (2) from a carrier material (1) comprising the following steps:
lifting the chip (2) by means of at least one needle (4),
wherein the chip (2) is lifted from the side of the chip (2) facing toward the carrier material (1)
wherein the lifting occurs in such a way that the at least one needle (4) includes at least one cutting edge (7) and the at least one needle (4) through the carrier material (1) lifts the chip (2), and the carrier material (1) as it is lifted, is cut through by at least one cutting edge (7).

15. The method for lifting a chip (2) from a carrier material (1) according to claim 14, wherein the cutting edge (7) is formed as a lateral edge along the front portion of the needle (4).

16. The method for lifting a chip (2) from a carrier material (1) according to claim 14 or 15, wherein the at least one needle (4) has a diameter (d) smaller or equal to 0.25 mm.

17. The method for lifting a chip (2) according to claim 14 or 15, from a carrier material (1), wherein
the ejection device is fitted with needles (4) depending on the area of the chip (2) to be lifted, with a needle density of at least one needle per 0.33 mm² of chip area.

18. Fabrication machine for lifting a chip from a carrier material and for taking up the chip to be further processed,
comprising an ejection device according to claim 1 or 2 for lifting the chip from the carrier material
and having a take-up tool for taking up the chip from the ejection device.
